(19) United States
(12) Patent Application Publication
(10) Pub. No.: US 2025/0200263 A1
(43) Pub. Date: Jun. 19, 2025

(54) APPARATUS AND METHOD OF ANALOG AND MIXED-SIGNAL CIRCUIT LAYOUT AUTOMATION

(71) Applicant: YUAN-JU CHAO, CUPERTINO, CA (US)

(72) Inventor: YUAN-JU CHAO, CUPERTINO, CA (US)

(21) Appl. No.: 18/545,870

(22) Filed: Dec. 19, 2023

(51) Int. Cl. G06F 30/38

(52) U.S. Cl. CPC G06F 30/38

(57) ABSTRACT

The present invention discloses a method for automating analog and mixed-signal circuit layout, with a primary focus on enhancing layout integrity. The proposed systematic top-down flow comprises six sequential steps, meticulously designed to ensure superior signal integrity while minimizing layout iteration cycles and significantly reducing development time. This innovative approach represents a substantial advancement in the field of analog circuit design automation, offering a streamlined and efficient process that is particularly advantageous for analog and mixed-signal applications. The method's systematic integration not only enhances the overall reliability of analog circuit layouts but also contributes to substantial time and resource savings in the product development lifecycle.

### BACKGROUND

Analog and mixed-signal circuit design is a crucial component in modern semiconductor industry. The increasing complexity of integrated circuits (ICs) and constant miniaturization of process nodes present significant challenges to analog and mixed-signal circuit design. Traditionally, the layout design of analog and mixed-signal circuits is manually performed by an experienced designer, which is labor-intensive, highly skill-dependent, time-consuming and often creates substantial risk for errors. Although some layout generators have been developed recently, their rule-based approach lacks the flexibility to accommodate diverse design requirements and they often fail to fully take into account the myriad of design constraints necessary in mixed-signal and analog circuit design.

While Electrical Design Automation (EDA) tools have significantly streamlined the automatic generation of layouts for digital circuits, the challenges are pronounced in analog integrated circuits. Analog layout requires a customized approach, addressing complexities such as matching, symmetry, layout-dependent effect, guarding, current density, parasitic resistance, and parasitic capacitance etc. Achieving optimal signal integrity involves extensive collaboration and iteration between circuit designers and layout professionals.

### SUMMARY

In one aspect, systems and methods are disclosed for automating analog and mixed-signal circuit layout, emphasizing layout integrity enhancement. The systematic top-down flow involves six key sequential steps:
Step 1: Device Placement
Step 2: Signal Integrity
Step 3: Signal Routing
Step 4: Optimization
Step 5: Report Generation
Step 6: Validation

Advantages of the above system may include one or more of the following. The system introduces a method for automating analog and mixed-signal circuit layout. Unlike traditional methods involving time-consuming iterations, this method employs a systematic top-down flow. The primary objectives are to meet user-defined signal integrity requirements and minimize overall layout development time. By addressing inherent complexities in analog layout, the method aims to enhance layout quality, minimizing human errors, and significantly reduce manual effort and enhance the efficiency of the design process.

This method represents an advancement in analog and mixed-signal circuit layout design, offering a streamlined and efficient process to ensure both reliability and adherence to project requirements. The automated, flexible and reliable approach to analog and mixed-signal circuit layout, ensures adaptability to the diverse analog circuit requirements, signal integrity, and compliance with design rules, while minimizing layout space and preventing man-made errors.

A more complete appreciation of the present invention and its improvements can be obtained by reference to the accompanying drawings, which are briefly summarized below, to the following detailed description of illustrative embodiments of the invention, and to the appended claims.

### BRIEF DESCRIPTION OF THE DRAWINGS

The accompanying drawings illustrate the automation top-down flow procedures and exemplary circuit designs, providing a visual comprehension of the implementation of the disclosed invention.

FIG. 1 lists the systematic top-down procedures of analog layout automation.

FIG. 2 illustrates a non-inverting amplifier in a closed-loop configuration.

FIG. 3 illustrates the exemplary two stage amplifier design.

FIG. 4 illustrates the layout subsequent to step 1 (Device Placement) execution of the procedure.

FIG. 5 illustrates the layout subsequent to step 2 (Signal Integrity) execution of the procedure.

FIG. 6 illustrates the layout following step 3 (Signal Routing) and step 4 (Optimization) of the procedure.

### DETAILED DESCRIPTION

The detailed description outlines the six-step top-down flow procedure for analog layout automation, emphasizing specific parameters and conditions. Each step is designed to meet various requirements and constraints, ensuring a coherent and effective design process.

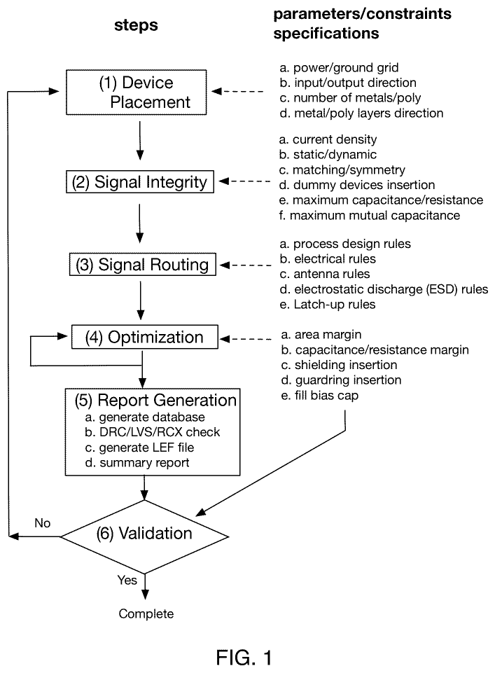

FIG. 1 lists the systematic top-down procedures of analog layout automation. The procedure consists of six key steps and corresponding parameters/constraints to ensure the layout integrity. Step 1 Device Placement is optimally arranging the circuit components including passive devices and active devices based on specified parameters on power/ground grid, input/output direction, number of metals and poly layer, metal/poly layer direction.

In Step 2, Signal Integrity, the procedure directly focuses on signal characteristics including current density, static/dynamic signals, matching/symmetry requirement, dummy device insertion, allowed maximum capacitance and resistance. The algorithm analyzes the imposed constraints on each signal, ascertaining the optimal routing width, length and spacing between signals. This analysis ensures an efficient configuration, aligning with the stringent criteria dictated by signal integrity considerations.

In Step 3, Signal Routing, the procedure connecting all the signals in accordance with the constraints established in Step 2, while adhering to a set of foundry design rules. These design rules include process design rules, electrical rules, antenna rules, electrostatic discharge (ESD) rules and latch-up rules. The spacing between critical signals is determined to mitigate noise coupling, and the routing length of crucial signals is minimized. This step ensures the precise and compliant interconnection of signals with optimized performance and integrity.

In Step 4, Optimization, the algorithm iteratively refines the layout based on specified area margin, capacitance/resistance margin criteria. Critical signals are shielded to minimize the noise interference. The required guarding is inserted to enhance the robustness of the circuit. Additionally, capacitance is added to static bias signals, ensuring the adherence to the stringent performance metrics.

In Step 5, Report Generation, the procedure automatically generates comprehensive reports encompassing essential checks and metrics. This includes Design Rule Check (DRC), Layout versus Schematic (LVS) check, RC extraction (RCX), and the production of Liberty Exchange Format (LEF) file. This reports provide a detailed analysis of the layout, ensuring compliance with established design rules and highlighting any deviations. The layout metrics are summarized, providing a comprehensive overview of the performance.

In Step 6, Validation, the primary objective is to confirm that the layout metrics align with the predefined design parameters and overall specifications. Each step is designed with corresponding parameters and specifications tailored to various conditions and requirements. The summary report undergoes a thorough comparison against the provided specification. Should the generated layout metrics fall short of the requirement, the procedure reverts back to step 1 for another iteration. This iterative process continues until the final output meets the designed specification. The sequential nature of the steps is critical in prioritizing the assessment of the certain parameters before others, ensuring a systematic top-down and effective design refinement.

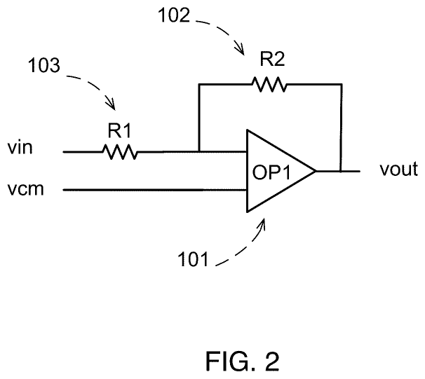

FIG. 2 illustrates a non-inverting amplifier in a closed-loop configuration. This exemplary circuit serves as a practical demonstration of the implementation of the automation flow alongside the step. It consists of 3 components 101 OP1, 102 R2 and 103 R1.

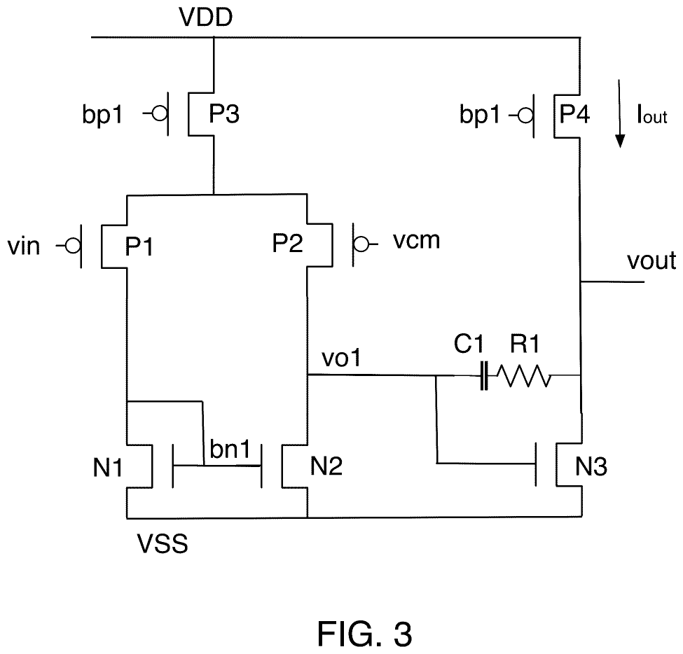

FIG. 3 illustrates an exemplary two-stage amplifier for OP1 of FIG. 2. This amplifier incorporates four PFET devices (P1/P2/P3/P4), three NFET devices (N1/N2/N3) and two passive devices R1/C1. There are three inputs (vin/vcm/bp1), some interconnected signals and single output signal (vout) in this configuration.

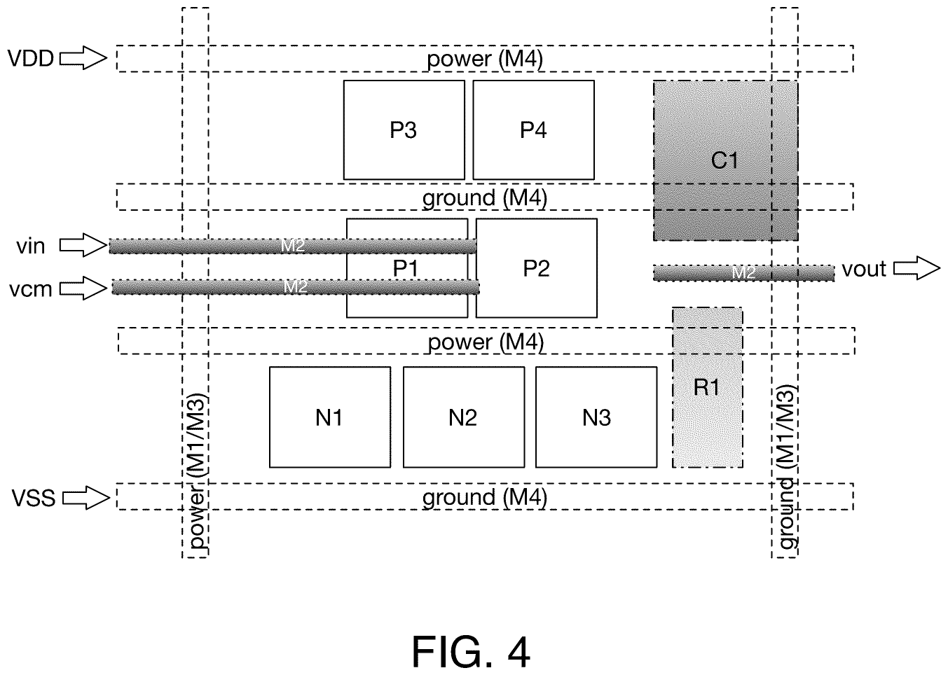

Starting with Step 1, power/ground (VDD/VSS), input/output direction, metal layer and direction parameters are defined. The subsequent illustration FIG. 4 shows the layout implementation post-Step 1 (Device Placement). This stage establishes a robust power/ground grid, positions inputs on the left side, and situates the output signal on the right side. Notably, the odd-numbered metal layers (M1/M3) are oriented vertically, while the even-numbered metal layers (M2/M4) route horizontally.

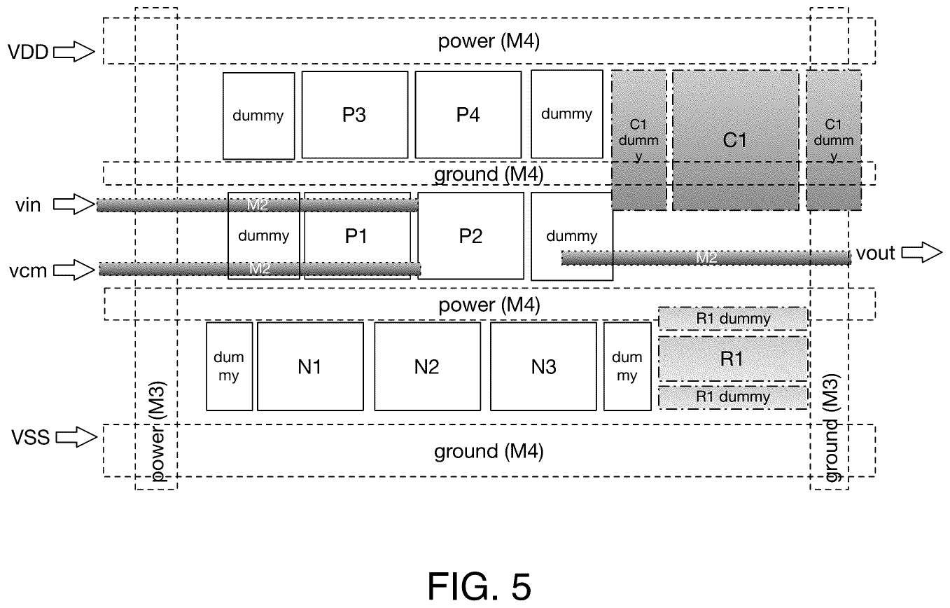

FIG. 5 provides a visual representation of the layout subsequent to the completion of Step 2 (Signal Integrity). This step addressees critical Signal Integrity parameters, including current density, characteristics of static signal and dynamic signals, dummy devices on-side, matching/symmetry requirement, and allowed maximum capacitance/resistance values.

As illustrated in FIG. 5. adjustments have been made to meet the prescribed current density requirement, notably by increasing the power/ground width. Dummy devices have been inserted on both sides of all devices, contributing to the matching and symmetric characteristics. To mitigate mutual coupling between dynamic signals vin/vcm, a specific spacing has been introduced. The overall area has been expanded to accommodate these modifications, ensuring an optimized layout.

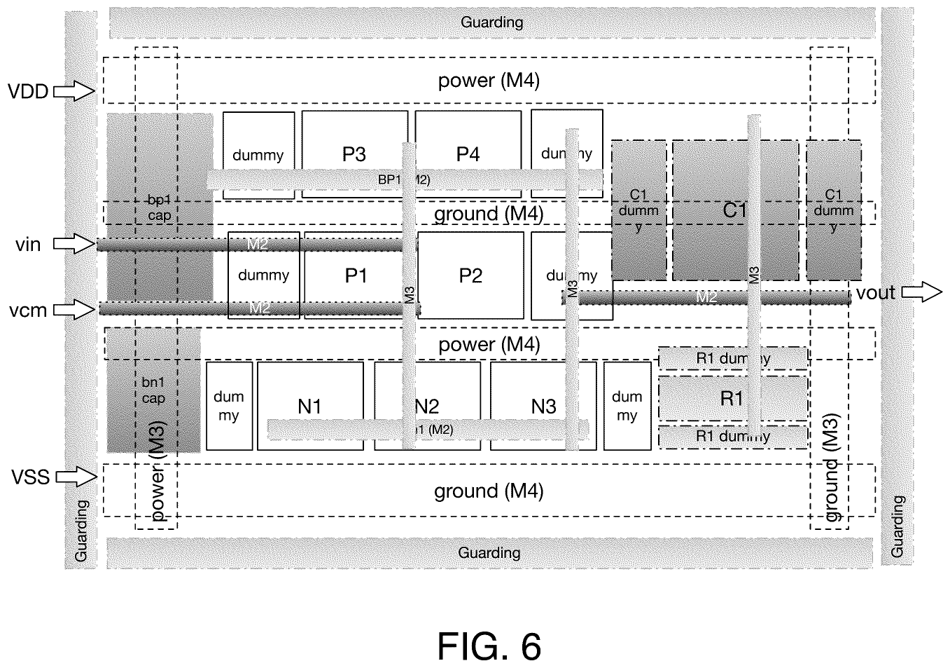

FIG. 6 illustrates the layout implementation to the execution of step 3 (Signal Routing) and 4 (Optimization) in the automation procedure. The internal signals are connected, the guarding is inserted around the circuitry. And empty space is filled with bias signal capacitors.

The procedure advances to Step 5, where all associated layout reports are automatically generated and summarized. These reports encompass crucial checks, including Design rule check (DRC), Layout versus Schematic (LVS) check, RC extraction (RCX), and the generation of Liberty Exchange Format (LEF) file. A pivotal aspect of the procedure involves looping back to Step 1 in the event that the summarized metric fall short of meeting the design specifications.

As shown in the above example, the method begins with arranging circuit components, including passive and active devices, based on predefined design parameters and overall specifications. This step ensures that the initial layout aligns with the expected performance metrics of the circuit, thereby setting the foundation for the rest of the process. This step of arrangement takes into account the electrical, physical, and operational characteristics of the devices to maximize the efficiency and functionality of the final circuit design.

The next step of the process involves analyzing signal integrity with one or more constraints on each signal and determining the optimal routing width, length, and spacing between signals. This critical analysis assures the provision of clear, correct and distortion-free signals, hence ensuring great functionality of the circuit. This step also involves the use of advanced computation algorithms to obtain the optimal parameters for signal routing, with the objective to minimize signal loss and maximize signal speed.

The third step is performing signal routing by connecting all signals in accordance with the one or more constraints, while adhering to a set of foundry design rules. This step essentially means creating pathways for the electrical signals to travel across the circuit. The purpose of following foundry design rules is to ensure manufacturability, reliability, and reproducibility of the circuit.

The following step is optimizing the analog and mixed-signal circuit layout through iterative layout refinements. The optimization methods may include techniques for minimizing area, power, noise, and other factors that impact the performance of a circuit. The iterative process systematically tests and enhances the design by making adjustments and re-running simulations until an optimal solution that meets the design's targets is found.

The method further incorporates generating one or more reports encompassing essential checks and metrics. These reports allow designers to monitor and confirm whether the iterative refinements are positively impacting the performance of the circuit.

Validation of the analog and mixed-signal circuit layout is then conducted to confirm that the layout metrics are within a predetermined threshold of the predefined design parameters and overall specifications. This ensures that the actual layout performance is within acceptable limits of the expected performance, indicating the readiness of the design for the next stage.

If the layout metrics are not within the predetermined threshold during validation, the steps of arranging, analyzing, routing, refining, generating reports and validating, are sequentially repeated until the threshold is met. This iterative nature of the process continues refining the layout until the final layout meets or surpasses all of the preset requirements and constraints, thus achieving a superior circuit design.

The one embodiment relates to a method for optimizing the arrangement of circuit components within an electronic device, wherein the method provides for the maximization of device efficiency and functionality. The process includes the deep consideration of various specific parameters, including but not limited to the power requirements, ground grid design, input/output (I/O) direction, the number of metal layers, the number of polysilicon layers, and the metal direction.

The method begins by receiving the specified parameters of the electronic device including power requirements, ground grid design, I/O direction, the quantity of metal layers, the quantity of polysilicon layers, and the metal direction. These parameters are utilized to establish optimal circuit component arrangements to ensure that the device is both highly operational and energy efficient. The power and ground grid designs assist in determining the ideal voltage necessities and current flow within the device. The parameters concerning the number of metal and polysilicon layers are crucial to the plan and construction of the microchip, influencing the overall performance and capabilities of the electronic device.

Furthermore, steering of the I/O interface dictates the routing path and communication pattern between the device and outer systems and the user, affecting the device's real-time responsiveness and reaction times. Meanwhile, the parameter of metal directionality also contributes to the optimization process of component arrangement, considering the ideal conductivity paths to guarantee maximum signal strength, signal integrity and to minimize cross talk and noise. Taken together, all these parameters enable the device's design to be tailored for specific user needs and operate at peak performance, demonstrating the effectiveness of the claimed ground-breaking method to arrange circuit components with greater precision and efficiency.

The method can optimize circuit design through meticulous analysis of signal integrity. The device receives multiple inputs, most notably current density, static signals, and dynamic signals with which it scrutinizes the design for potential flaws or areas of inefficiency. The current density input allows the one embodiment to gauge the number of charges passing through the section under consideration, thereby providing information about electrical consumption that could affect the system's performance and its corresponding utility.

The method recommends matching layout and layout symmetry, a feature that has a direct bearing on the reliability and accuracy of circuit operation. By ensuring that the layout is identical on both sides of a centerline of symmetry, the chances of distortions or anomalies in the circuitry are minimized. Similarly, the one embodiment accommodates the input of dummy devices and their consequent insertion into the circuit. Dummy devices are useful as proxies for real system components when simulating certain conditions, thus improving the diagnostics and error detection capabilities of the overall solution.

One embodiment can manage maximum mutual capacitor coupling, allowed maximum capacitance, and maximum resistance requirements. By considering the maximum mutual capacity coupling, the device helps in reducing electrostatic interference which can impede signal transmissions. Furthermore, through its provision for allowable maximum capacitance and resistance, a range of tolerances is provided, allowing the overall circuit to remain within safe operating conditions. These features together make the one embodiment a robust solution for efficient and accurate circuit design.

The system can mitigate noise coupling between signal connections while adhering to a set of foundry rules. These foundry rules encompass process design rules, electrical rules, antenna rules, Electrostatic Discharge (ESD) rules and latch-up check rules. Ensuring that signal connections comply with these rules whilst attenuating extraneous noise is a performance characteristic essential to the reliability and operational efficiency of semiconductor devices. The signal connections are scrutinized and checked for compliance with the set of foundry rules. This rule-checking mechanism is integrated into the methodology of the one embodiment to monitor, regulate, and validate the signal routing. The mechanism ensures consistent rule adherence thus maintaining quality and device performance. The set of foundry rules act as parameters governing key aspects of the manufacturing process including process design, electrical safety, antenna design and ESD prevention, thereby addressing various potential risk factors involved in semiconductor manufacturing.

The mitigation of noise coupling between signals refers to the unwanted transfer of signals between different points in a circuit, which can distort the transmitted signal and impair the performance of the device. By employing noise mitigation strategies during the signal routing process, this one embodiment safeguards the integrity of signals processed within the device, ensuring a clear, precise signal transmission free from noise interference

The present one embodiment pertains to a system and methodology for enhancing robustness and performance parameters of electronic component layouts. Numerous parameters are specified for iterative refinement, including but not limited to area margin, resistance margin, capacitance margin, routing capacitance, mutual capacitance, and routing resistance. These parameters collectively form a procedural structure that allows for consistent recalibration and optimization of the electronic layout. The iterative refinement process enables the system to reach optimal reconciliation between constraints, leading to improved component performance and thus, increasing the robustness of the electronic layout.

Further, one embodiment recognizes the necessity of countering potential noise interference which can lead to compromised performance. To achieve this, a method for mitigating noise interference is put in place. In order to further minimize noise coupling, a shielding mechanism is introduced to the system. The shielding creates a barrier that absorbs or diverts the noise, thereby significantly reducing its transmission to the component layout. This gigantic step is crucial in ensuring the stability and the fidelity of signals passing through the electronic component layout, and overall, enhancing system reliability.

One embodiment introduces the feature of a guard ring and its strategic placement, along with one or more bias signal capacitors, within empty spaces of the layout. This technique enhances performance by containing potential leakage currents and addressing noise issues. The introduction of bias signal capacitors in the layout serves the purpose of reducing voltage fluctuations, thereby improving the circuit's speed performance. The ability to fit these components within empty spaces of the layout exemplifies space optimization, a unique feature of this one embodiment. This technique not only saves valuable real estate within the component layout but also reduces manufacturing costs, contributing to the industry's demand for economical efficiency.

The method includes generating reports and it further comprises generating a layout database, running a Design rule check (DRC), a Layout versus Schematic (LVS) check, an RC extraction (RCX), generating a Liberty Exchange Format (LEF) file, and generating an analytical summary report and layout metrics. These steps are carried out sequentially and are interdependent, resulting in high-quality, efficient, and reliable report generation.

In order to perform these functions, a layout database is first created. This represents the first step in the method and is crucial in storing the design layout information. This information typically includes rules for the manufacture of semiconductor devices, concerning the physical dimensions of the device, the spacing rules, as well as the arrangement of different sections of a chip. Following the generation of this layout database, the method carries out a series of design checks. This involves running a Design rule check (DRC) that verifies whether the physical layout of a particular chip layout meets the specified design rules. Additionally, a Layout versus Schematic (LVS) check is performed that validates whether a particular layout corresponds to the expected schematic or circuit description. This is critical to ensure that the manufacturing process will produce a working chip.

The method then extracts Resistance-Capacitance (RC) values, a process known as RC extraction (RCX). RCX is a significant procedural step that occurs during the physical verification phase in the production of integrated circuits. After executing the RCX, the method generates a Liberty Exchange Format (LEF) file. This file essentially summarizes abstract information about cells in the circuit design that act as a glossary for the tools used during chip design. The concluding step in the method is the generation of evaluative reports for the layout database. These include an analytical summary report that distills the check results and structural recommendations for modifications and improvements. It also includes a generation of layout metrics that offer a statistical overview of the design's attributes such as the number of transistors, gate size, and the likes. Together, these steps provide a comprehensive method for creating reports that are both insightful and precise.

The method includes taking into account various layout metrics, including area, power, delay or any other physical characteristics that may need consideration based on the requisite application. Predetermined specifications and constraints determine the selection of these metrics, ensuring a focus on what is most important for the specific design at hand. The method enables comparison of these metrics for different device placements, aiming to make an optimal selection achieving highest efficiency and meeting all predefined requirements.

In detail, the method operates by generating a database layout followed by evaluating various metrics for the current device placement. These metrics are meticulously measured and compared against predetermined specifications and constraints. If these comparisons fail to meet the predefined specifications, the method initiates another iteration from step 1. This recursive process allows for accurate and efficient optimization of device placement by ensuring each metric meets its respective constraints and aligns perfectly with its specifications. By such iterations, design trade-offs between different placement strategies can be evaluated and the best possible device placement can be achieved.

Another important aspect of the invented method is the generation of database layout metrics in each iteration. These metrics provide insightful information about the layout's performance in the areas of power, delay, and area, among others. The generated metrics prove essential in validating the optimal nature of the device placements, providing data on their efficiency and the improvements achieved in each iteration. By comparing these metadata with predefined specifications, the system ensures that device placement aligns with its intended purpose and meets or even exceeds the predetermined specifications. In its consideration of an array of metrics, the one embodiment invariably provides for the operation of an incredibly powerful, efficient, and adaptable optimizer for device placement.

The systematic method for designing analog circuits based upon algorithm optimization is specifically aimed at addressing the challenges present in traditional techniques, which often fail to balance between noise coupling, rule compliance, and area limitation. The inventive method seeks not only the preservation of signal integrity but also better adaptability to diverse analog circuit requirements. It involves an innovative top-down procedure that seamlessly incorporates variant design parameters and constraints specified for each step of the design process, thereby optimizing the entire circuitry for high-level performance.

The inventive top-down approach where the design parameters and constraints are allotted at every step. These parameters could range from power line noise specifications to limits imposed on circuit area. The algorithm then iteratively refines the analog circuitry by optimizing these varying parameters step-by-step, striving to achieve the perfect balance between rules compliance, area occupancy, and noise coupling. This optimization quest improves the signal-to-noise ratio, maintains the circuit's physical areas within specified limits, and adheres to the established design guidelines, subsequently enhancing the overall performance of the analog circuit.

Importantly, the one embodiment's innovative application of the algorithm enables it to adapt to a wide array of specific circuit requirements. This adaptability makes it immensely flexible, giving it the capacity to meet the needs of a broad spectrum of analog circuits while ensuring robust signal integrity. It is this unique combination of rule-based design constraints, area limit considerations, and noise coupling that makes the inventive method stand out in the analog circuit design space. It offers an efficient, accurate, and flexible means for designing analog circuits that can cope with contrasting, often conflicting, sets of design rules, thereby significantly improving the areas of signal integrity and noise handling.

The present one embodiment pertains to a method that primarily focuses on enhancing the adaptability and flexibility during the integration of a synthesized layout to an upper level. In existing systems, the incorporation of the synthesized layout to a higher level often faces challenges due to stringent parameters limiting the integration process. These systems also lack adaptability to accommodate evolving preferences, leading to a decrease in optimization. The present one embodiment proposes an innovative approach to revolutionize this process by providing a scheme that allows modifications through the adjustment of parameters corresponding to specific steps.

The methodology introduced by the one embodiment operates by increasing the flexibility of during the integration phase of a synthesized layout. This increase in flexibility allows the easy formation of the design chain with a higher level block. It not only facilitates smoother integration but also provides the capacity to tweak the process as per the evolving needs of users or design requirements. The adjustments are done by altering parameters linked to certain steps within the integration process. The mentioned steps include but are not limited to, the placement of the synthesized layout, the routing of the synthesized layout, and the validation of the integrated layout.

A unique factor of this one embodiment is the capability to accommodate evolving preferences. The one embodiment recognizes the dynamic nature of preferences in the integration process and addresses it efficiently through its adaptable mechanism. As such, the one embodiment ensures a shift away from a rigid integration process to a more fluid one that can evolve and adapt to suit varying process requirements. By enabling modifications and adjustments to parameters at specific steps, the one embodiment allows for optimization and adaptability not found in existing systems. This level of adaptability in the integration process leads to more efficient and personalized design processes.

One embodiment relates to a method for automatically synthesizing an analog or mixed-signal circuit layout, with design parameters explicitly specified for each step involved in the synthesis. The six sequential steps may encompass identifying user-defined signal integrity parameters, developing a schematic corresponding to the circuit design, determining optimal layout orientations, allocating circuit components, routing the interconnections, and performing a final validation check. The one embodiment enables the automation of tedious and complex design steps in the circuit layout process, thereby increasing efficiency, reducing human error, and providing a reliable, high-quality design.

The method initiates by engaging user-defined signal integrity requirements. These parameters can comprise data rate, signal-to-noise ratio, bit error rate, jitter etc. Followed by which, a compatible schematic is devised for the circuit. The robust engineering design principles are enforced in terms of thermal characteristics, electromigration constraints, and circuit reliability. Checks and balances for impedance mismatching and crosstalk effects are also implemented. Following the schematic design, the third step involves optimal layout orientations for the circuit components, considering aspects like component sizes, interconnect distances, alignment, and proximity to other components.

Subsequently, the fourth phase caters to the allocation of circuit components within the defined layout orientations. Packing algorithms are typically utilized for this. The fifth step involves routing the interconnections between the allocated components, in accordance with optimal wire length and minimal interference. The method employs routing algorithms that consider the uniqueness of the analog or mixed-signal circuit such as signal paths, shielding needs, and frequency overlaps. Finally, an all-inclusive validation check is incorporated to ensure that the implemented design meets the initial user-defined signal integrity requirements. In case of discrepancies, modifications in the implementation are suggested or executed automatically until the requirements are met. The benefit of the method is that it streamlines and automates the circuit layout design process, thereby improving the integrity, consistency, speed of design, and throughput of the overall analog or mixed-signal circuit synthesis process.

In summary, the disclosed method and apparatus for analog and mixed-signal circuit layout automation present a systematic approach to address the challenges associated with analog integrated circuits. By introducing a fixed and sequential six-step process, this innovation not only ensures superior signal integrity but also significantly reduces the time and effort traditionally required in the layout development phase. The incorporation of specific design parameters for each step underscores the adaptability and versatility of the proposed solution, making it a robust and efficient tool for various analog and mixed-signal circuit applications. This inventive approach offers a reliable, streamlined, and resource-efficient solution for complicated analog layouts.

Additionally, the flexibility of the method becomes evident during the integration of the implemented layout to the upper level. Modifications can be swiftly made by adjusting parameters for specific steps to accommodate changing preferences. For example, if the desired output signal position is on the lower side rather than the right side, this adjustment can be easily achieved by modifying parameters in Step 1, showcasing the versatility and user-friendly nature of the proposed methodology.

Various modifications and alterations of the invention will become apparent to those skilled in the art without departing from the spirit and scope of the invention, which is defined by the accompanying claims. It should be noted that steps recited in any method claims below do not necessarily need to be performed in the order that they are recited. Those of ordinary skill in the art will recognize variations in performing the steps from the order in which they are recited. In addition, the lack of mention or discussion of a feature, step, or component provides the basis for claims where the absent feature or component is excluded by way of a proviso or similar claim language.

While various embodiments of the present invention have been described above, it should be understood that they have been presented by way of example only, and not of limitation. The various diagrams may depict an example architectural or other configuration for the invention, which is done to aid in understanding the features and functionality that may be included in the invention. The invention is not restricted to the illustrated example architectures or configurations, but the desired features may be implemented using a variety of alternative architectures and configurations. Indeed, it will be apparent to one of skill in the art how alternative functional, logical or physical partitioning and configurations may be implemented to implement the desired features of the present invention. Also, a multitude of different constituent module names other than those depicted herein may be applied to the various partitions. Additionally, with regard to flow diagrams, operational descriptions and method claims, the order in which the steps are presented herein shall not mandate that various embodiments be implemented to perform the recited functionality in the same order unless the context dictates otherwise.

Although the invention is described above in terms of various exemplary embodiments and implementations, it should be understood that the various features, aspects and functionality described in one or more of the individual embodiments are not limited in their applicability to the particular embodiment with which they are described, but instead may be applied, alone or in various combinations, to one or more of the other embodiments of the invention, whether or not such embodiments are described and whether or not such features are presented as being a part of a described embodiment. Thus the breadth and scope of the present invention should not be limited by any of the above-described exemplary embodiments.

Terms and phrases used in this document, and variations thereof, unless otherwise expressly stated, should be construed as open ended as opposed to limiting. As examples of the foregoing: the term “including” should be read as meaning “including, without limitation” or the such as; the term “example” is used to provide exemplary instances of the item in discussion, not an exhaustive or limiting list thereof; the terms “a” or “an” should be read as meaning “at least one,” “one or more” or the such as; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Hence, where this document refers to technologies that would be apparent or known to one of ordinary skill in the art, such technologies encompass those apparent or known to the skilled artisan now or at any time in the future.

A group of items linked with the conjunction “and” should not be read as requiring that each and every one of those items be present in the grouping, but rather should be read as “and/or” unless expressly stated otherwise. Similarly, a group of items linked with the conjunction “or” should not be read as requiring mutual exclusivity among that group, but rather should also be read as “and/or” unless expressly stated otherwise. Furthermore, although items, elements or components of the invention may be described or claimed in the singular, the plural is contemplated to be within the scope thereof unless limitation to the singular is explicitly stated.

The presence of broadening words and phrases such as “one or more,” “at least,” “but not limited to” or other such as phrases in some instances shall not be read to mean that the narrower case is intended or required in instances where such broadening phrases may be absent. The use of the term “module” does not imply that the components or functionality described or claimed as part of the module are all configured in a common package. Indeed, any or all of the various components of a module, whether control logic or other components, may be combined in a single package or separately maintained and may further be distributed across multiple locations.

Additionally, the various embodiments set forth herein are described in terms of exemplary block diagrams, flow charts and other illustrations. As will become apparent to one of ordinary skill in the art after reading this document, the illustrated embodiments and their various alternatives may be implemented without confinement to the illustrated examples. For example, block diagrams and their accompanying description should not be construed as mandating a particular architecture or configuration.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. A method for top-down analog and mixed-signal circuit layout automation, comprising:
arranging circuit components including passive devices and active devices based on predefined design parameters and overall specification;
analyzing signal integrity with one or more constraints on each signal and ascertaining the optimal routing width, length and spacing between signals;
performing signal routing by connecting all signals in accordance with the one or more constraints while adhering to a set of foundry design rules;
optimizing the analog and mixed-signal circuit layout through iterative layout refinements;
generating one or more reports encompassing essential checks and metrics; and
validating the analog and mixed-signal circuit layout to confirm the layout metrics are within a predetermined threshold of the predefined design parameters and overall specifications and otherwise sequentially repeating steps 1 to 6 until the predetermined threshold is met.

2. The method of claim 1, wherein the arranging of the circuit components comprises receiving specified parameters of power, ground grid, input/output direction, number of metal layer, number of polysilicon layer, and metal direction.

3. The method of claim 1, wherein the analyzing signal integrity further comprises receiving current density, static signals, dynamic signals, matching layout, layout symmetry, dummy devices insertion, maximum mutual capacitor coupling, allowed maximum capacitance and maximum resistance requirements.

4. The method of claim 1, wherein the set of foundry rules include process design rules, electrical rules, antenna rules and Electrostatic discharge (ESD) rules, latch-up check and adherence, and wherein the signal routing further comprises checking for signals connection compliance with the set of foundry rules while mitigating noise coupling between signals.

5. The method of claim 1, wherein the area margin, resistance margin, capacitance margin, the routing capacitance, mutual capacitance, routing resistance parameters are specified for iterative refinement, further comprising mitigating noise interference; minimizing noise coupling with a shielding; inserting a guard ring and placing one or more bias signal capacitors in an empty area of the layout.

6. The method of claim 1, wherein the generating of the reports further comprises generating a layout database; running a Design rule check (DRC), a Layout versus Schematic (LVS) check, an RC extraction (RCX), generating a Liberty Exchange Format (LEF) file, and generating an analytical summary report and layout metrics.

7. The method of claim 1, wherein the generated database layout metrics in step 5 are compared against with predefined specifications and constraints, comprising reverting to step 1 for another device placement iteration if the generated layout metrics fail to meet the specifications.

8. The method of claim 1, wherein the systematic top-down procedure incorporates variant design parameters and constraints specified for each step, the algorithm optimizes the balance between noise coupling, rule compliance and area limitation, ensuring signal integrity and adaptability to the diverse analog circuit requirements.

9. The method of claim 1, comprising increasing a flexibility of during integration of the synthesized layout to an upper level and modifications are done by adjusting parameters for specific steps to accommodate evolving preferences.

10. The method of claim 1, comprising automatically synthesizing an analog or mixed-signal circuit layout with the six sequential steps and design parameters explicitly specified for each step, wherein the synthesized layout implementation attains user-defined signal integrity requirements.

11. A system to perform top-down circuit layout automation, comprising:
a processor; and
computer readable executable by the processor to:
arrange circuit components including passive devices and active devices based on predefined design parameters and overall specification;
analyze signal integrity with one or more constraints on each signal and ascertaining the optimal routing width, length and spacing between signals;
perform signal routing by connecting all signals in accordance with the one or more constraints while adhering to a set of foundry design rules;
optimize the analog and mixed-signal circuit layout through iterative layout refinements;
generate one or more reports encompassing essential checks and metrics; and
validate the analog and mixed-signal circuit layout to confirm the layout metrics are within a predetermined threshold of the predefined design parameters and overall specifications and otherwise sequentially repeating steps 1 to 6 until the predetermined threshold is met.

12. The system of claim 11, wherein the code to arrange the circuit components comprises means for receiving specified parameters of power, ground grid, input/output direction, number of metal layer, number of polysilicon layer, and metal direction.

13. The system of claim 11, wherein the code to analyze signal integrity further comprises means for receiving current density, static signals, dynamic signals, matching layout, layout symmetry, dummy devices insertion, maximum mutual capacitor coupling, allowed maximum capacitance and maximum resistance requirements.

14. The system of claim 11, wherein the set of foundry rules include process design rules, electrical rules, antenna rules and Electrostatic discharge (ESD) rules, latch-up check and adherence, and wherein the signal routing further comprises checking for signals connection compliance with the set of foundry rules while mitigating noise coupling between signals.

15. The system of claim 11, wherein the area margin, resistance margin, capacitance margin, the routing capacitance, mutual capacitance, routing resistance parameters are specified for iterative refinement, further comprising means for mitigating noise interference; minimizing noise coupling with a shielding; inserting a guard ring and placing one or more bias signal capacitors in an empty area of the layout.

16. The system of claim 11, wherein the code to generate reports further comprises means for generating a layout database; running a Design rule check (DRC), a Layout versus Schematic (LVS) check, an RC extraction (RCX), generating a Liberty Exchange Format (LEF) file, and generating an analytical summary report and layout metrics.

17. The system of claim 11, wherein the generated database layout metrics in step 5 are compared against with predefined specifications and constraints, comprising reverting to step 1 for another device placement iteration if the generated layout metrics fail to meet the specifications.

18. The system of claim 11, comprising a systematic top-down code with variant design parameters and constraints specified for each step, the code optimizes the balance between noise coupling, rule compliance and area limitation, ensuring signal integrity and adaptability to the diverse analog circuit requirements.

19. The system of claim 11, comprising means for increasing flexibility of during integration of the synthesized layout to an upper level and modifications are done by adjusting parameters for specific steps to accommodate evolving preferences.

20. The system of claim 11, comprising code to automatically synthesize an analog circuit layout with the six sequential steps and design parameters explicitly specified for each step, wherein the synthesized layout implementation attains user-defined signal integrity requirements.
